(19) United States
(12) Patent Application Publication
(10) Pub. No.: US 2026/0324304 A1
(43) Pub. Date: Oct. 15, 2026

(54) VARIABLE RESISTANCE MATERIAL, MATERIAL FOR SWITCH ELEMENT, SWITCH LAYER, SWITCH ELEMENT, AND STORAGE DEVICE

(71) Applicants: TOHOKU UNIVERSITY, Sendai-shi, Miyagi (JP); NIPPON ELECTRIC GLASS CO., LTD., Otsu-shi, Shiga (JP)

(72) Inventors: Yuji SUTOU, Sendai-shi (JP); Yi SHUANG, Sendai-shi (JP); Kosuke KARAKIDA, Otsu-shi (JP); Yoshimasa MATSUSHITA, Otsu-shi (JP); Fumio SATO, Otsu-shi (JP)

(21) Appl. No.: 19/476,380

(22) PCT Filed: Mar. 19, 2024
(86) PCT No.: PCT/JP2024/010661

§ 371 Date: Oct. 17, 2025

(30) Foreign Application Priority Data
Apr. 20, 2023 (JP) 2023-069443
Jul. 12, 2023 (JP) 2023-114479

(51) Int. Cl. H10N 70/00; H10B 61/00; H10B 63/00; H10B 63/10

(52) U.S. Cl. CPC H10N 70/8828; H10B 63/80; H10N 70/826; H10B 61/10; H10B 63/10

(57) ABSTRACT

Provided is a variable-resistance material, a material for a switch element, a switch layer, a switch element, and a memory device, all having excellent OTS characteristics. [Solution] A variable-resistance material contains Te, wherein when a current density of the variable-resistance material upon application of one-half a threshold voltage thereto is defined as an OFF current density, the OFF current density is not more than 3.1×10² A/cm².

### TECHNICAL FIELD

The present invention relates to variable-resistance materials, materials for switch elements, switch layers, switch elements, and memory devices.

### BACKGROUND ART

Next-generation non-volatile memory devices are attracting attention as alternative memory devices to a NAND flash memory. For example, a resistance-variable memory device and a phase-change memory device are proposed as next-generation non-volatile memory devices and are being under development for increasing the capacity and the processing speed.

Furthermore, a cross-point memory device is also attracting attention as a structure for a next-generation non-volatile memory device (Patent Literatures 1 and 2). The cross-point memory device includes word lines, bit lines orthogonal to the word lines in plan view, and memory elements and switch elements arranged at the intersections between the word lines and the bit lines in plan view. A transistor or a diode is conventionally used as the switch element, but the use of an ovonic threshold switch (OTS) element variable in resistance according to the applied voltage has attracted attention with increasing size reduction, capacity, and integration of memory devices.

### CITATION LIST

### Patent Literature

### [PTL 1]

JP-A-2006-086526

### [PTL 2]

JP-A-2018-164085

### Non-Patent Literature

### [NPL 1]

Lencer, D. et al., “A map for phase-change materials”, Nat. Mater. 7, 972-977 (2008)

### SUMMARY OF INVENTION

### Technical Problem

An OTS element is required to exhibit large resistance changes with applied voltage (i.e., have excellent OTS characteristics) in order to obtain a stable switching behavior.

In view of the foregoing, the present invention has an object of providing a variable-resistance material, a material for a switch element, a switch layer, a switch element, and a memory device, all having excellent OTS characteristics.

### Solution to Problem

A description will be given below of aspects of a variable-resistance material, a material for a switch element, a switch layer, a switch element, and a memory device which can solve the above problem.

A variable-resistance material of aspect 1 is a variable-resistance material containing Te, wherein when a current density of the variable-resistance material upon application of one-half a threshold voltage thereto is defined as an OFF current density, the OFF current density is not more than 3.1×10² A/cm². Herein, the threshold voltage means a voltage value at the time the electrical resistance value rapidly changes from a high-resistance state to a low-resistance state. The OFF current density means a value obtained by dividing a value (OFF current value) of a current that flows through the material upon application of one-half the threshold voltage thereto by the contact area of the material with an electrode.

A variable-resistance material of aspect 2 is the variable-resistance material according to aspect 1, wherein, additionally, when a current density of the variable-resistance material upon application of a voltage not less than the threshold voltage thereto is defined as an ON current density, the ON current density is preferably not less than 1×10⁶ A/cm². Herein, the ON current density means a value obtained by dividing a value (ON current value) of a current that flows through the material upon application of a voltage not less than the threshold voltage thereto by the contact area of the material with an electrode.

A variable-resistance material of aspect 3 is the variable-resistance material according to aspect 1 or 2 and preferably has a carrier mobility of not more than 5×10⁻³ cm²/Vs.

A variable-resistance material of aspect 4 is the variable-resistance material according to any one of aspects 1 to 3, wherein when a current density of the variable-resistance material upon application of a voltage not less than the threshold voltage thereto is defined as an ON current density, an ON/OFF current ratio obtained by dividing the ON current density by the OFF current density is preferably not less than 1×10⁴.

A variable-resistance material of aspect 5 is the variable-resistance material according to any one of aspects 1 to 4, wherein the threshold voltage is preferably within a range of 0.5 V to 10 V.

A variable-resistance material of aspect 6 is the variable-resistance material according to any one of aspects 1 to 5 and preferably contains, in terms of atomic %, 0.1% to 50% Ge and 40% to 90% Te.

A variable-resistance material of aspect 7 is the variable-resistance material according to any one of aspects 1 to 6 and preferably contains, in terms of atomic %, 1% to 59% Si+Al+Ga+Sn+Bi+Cu+Ag+Zn+Y+In+Ca+Mg.

A variable-resistance material of aspect 8 is the variable-resistance material according to any one of aspects 1 to 7 and preferably contains, in terms of atomic %, 0% to less than 5% Sb.

A variable-resistance material of aspect 9 is the variable-resistance material according to any one of aspects 1 to 7 and is preferably substantially free of Sb, Se, and As.

A variable-resistance material of aspect 10 is the variable-resistance material according to any one of aspects 1 to 9 and preferably has an oxygen content of less than 1 atomic %.

A variable-resistance material of aspect 11 is the variable-resistance material according to any one of aspects 1 to 10 and is preferably a thin film.

A material for a switch element of aspect 12 is made of the variable-resistance material according to any one of aspects 1 to 11.

A switch layer of aspect 13 is made of the variable-resistance material according to any one of aspects 1 to 11.

A switch element of aspect 14 includes: the switch layer according to aspect 13; and a first electrode disposed on the switch layer.

A switch element of aspect 15 includes: a switch layer; a first electrode disposed on the switch layer; and a second electrode opposed to the first electrode with the switch layer in between, wherein the switch layer is made of a variable-resistance material which contains Te and in which when a current density of the variable-resistance material upon application of one-half a threshold voltage thereto is defined as an OFF current density, the OFF current density is not more than 3.1×10² A/cm².

A switch element of aspect 16 is the switch element according to aspect 15, wherein, preferably, the first electrode is disposed on an outer periphery of the switch layer and the second electrode is disposed on an inner periphery of the switch layer.

A switch element of aspect 17 is the switch element according to aspect 15 or 16, wherein the first electrode and the second electrode are preferably at least one selected from among tungsten, titanium, copper, platinum, tungsten nitride, and titanium nitride.

A switch element of aspect 18 is the switch element according to any one of aspects 15 to 17, wherein an ionicity r_{σ}′ and a hybridization r_{π}⁻¹ of the switch layer preferably satisfy the respective following values:

r_{σ}′≥0.05

r_{π}⁻¹≤2.0

A switch element of aspect 19 is the switch element according to any one of aspects 15 to 18, wherein where a represents a carrier activation energy of the switch element upon application of an applied voltage of 0.15 V to the switch layer and b represents a carrier activation energy of the switch element upon application of an applied voltage of 0.30 V to the switch layer, the switch element preferably satisfies a/b<1.

A memory device of aspect 20 preferably includes: the switch element according to any one of aspects 15 to 19.

A memory device of aspect 21 preferably includes: the switch element according to any one of aspects 15 to 19; and a memory element.

A memory device of aspect 22 is a memory device including a laminate in which a switch element and a memory element are layered, wherein: the switch element includes a switch layer and a first electrode disposed on the switch layer; the switch layer is made of a variable-resistance material in which when a current density of the variable-resistance material upon application of one-half a threshold voltage thereto is defined as an OFF current density, the OFF current density is not more than 3.1×10² A/cm²; and the memory element is made of at least one of a variable-resistance memory element, a magnetoresistive memory element, a phase-change memory element, and a ferroelectric memory element.

### Advantageous Effects of Invention

The present invention enables provision of a variable-resistance material, a material for a switch element, a switch layer, a switch element, and a memory device, all having excellent OTS characteristics.

### BRIEF DESCRIPTION OF DRAWINGS

FIG. 1 is a schematic cross-sectional view of a switch element according to one embodiment of the present invention.

FIG. 2 is a schematic cross-sectional view of a memory element according to one embodiment of the present invention.

FIG. 3 is a schematic stereogram of a memory device according to a first embodiment of the present invention.

FIG. 4 is a schematic partially enlarged stereogram of the memory device according to the first embodiment of the present invention.

FIG. 5 is a schematic stereogram of a modification of the memory device according to the first embodiment of the present invention.

FIG. 6 is a schematic stereogram of a memory device according to a second embodiment of the present invention.

FIG. 7 is a schematic stereogram of a modification of the memory device according to the second embodiment of the present invention.

FIG. 8 is a graph on which, as for switch layers, the ionicity r_{σ}′ and the hybridization r_{π}⁻¹ are plotted.

### DESCRIPTION OF EMBODIMENTS

Hereinafter, a description will be given of preferred embodiments. However, the following embodiments are merely illustrative and the present invention is not limited to the following embodiments. In the following description, “%” refers to “atomic %” unless otherwise stated. In the present invention, “x+y+z+ . . . ” means the total content of components. In this case, the variable-resistance material need not necessarily contain all of the components as essential components and may not be free of one or some of the components (that is, the content of the one or some of the components may be 0%). The expression “A % to B % x+y+z+ . . . ” includes, for example, the case of “x=0% and A % to B % y+z+ . . . ” and the case of “x=0%, y=0%, and A % to B % z+ . . . ”.

### <Variable-Resistance Material>

A variable-resistance material according to the present invention is a variable-resistance material containing Te and has a feature that when a current density of the variable-resistance material upon application of one-half a threshold voltage thereto is defined as an OFF current density, the OFF current density is not more than 3.1×10² A/cm².

The inventors found that a variable-resistance material having an OFF current density meeting a predetermined value has excellent OTS characteristics. The OTS characteristics mean characteristics that a chalcogenide-based thin film changes the resistance value with applied voltage. The details are as follows. A variable-resistance material exhibits high resistance in an initial state (an OFF state). When in this state the voltage applied to the variable-resistance material is increased, the variable-resistance material maintains a high-resistance state before a threshold voltage is exceeded, and it rapidly switches to a low-resistance state (an ON state) when the threshold voltage is exceeded. When the applied voltage is decreased from an ON state, the variable-resistance material returns to an OFF state. In a variable-resistance material having excellent OTS characteristics, this resistance difference between the high-resistance state and the low-resistance state is large. In other words, the difference between the current density in the low-resistance state and the current density in the high-resistance state (i.e., the ON/OFF current ratio) is large. Therefore, such a variable-resistance material can be used stably as a switch layer and a switch element. Herein, the ON/OFF current ratio means a value obtained by dividing the ON current density by the OFF current density.

In the variable-resistance material according to the present invention, when its current density upon application of one-half the threshold voltage thereto is defined as an OFF current density, the upper limit of the OFF current density is not more than 3.1×10² A/cm², preferably not more than 3×10² A/cm², more preferably not more than 2.8×10² A/cm², and particularly preferably not more than 2.6×10² A/cm². When the OFF current density meets the above value, the ON/OFF current ratio can be easily increased. Therefore, the material can obtain stable OTS characteristics. The lower limit of the OFF current density is not particularly limited, but may be not less than 5×10⁻³ A/cm², not less than 6×10⁻³ A/cm² or not less than 1×10⁻² A/cm².

In the variable-resistance material according to the present invention, when its current density upon application of a voltage not less than the threshold voltage thereto is defined as an ON current density, the lower limit of the ON current density is preferably not less than 1×10⁶ A/cm², not less than 2×10⁶ A/cm², not less than 3.1×10⁶ A/cm², not less than 3.2×10⁶ A/cm², not less than 3.5×10⁶ A/cm², not less than 4.1×10⁶ A/cm², not less than 4.2×10⁶ A/cm², not less than 4.3×10⁶ A/cm² or not less than 4.4×10⁶ A/cm², and particularly preferably not less than 4.5×10⁶ A/cm². When the ON current density meets the above value, the ON/OFF current ratio can be further increased. The upper limit of the ON current density is not particularly limited, but may be, for example, not more than 1×10⁹ A/cm², not more than 1×10⁸ A/cm² or not more than 1×10⁷ A/cm².

In the variable-resistance material according to the present invention, the lower limit of the ON/OFF current ratio is preferably not less than 1×10⁴, not less than 1.2×10⁴, not less than 1.5×10⁴, not less than 1.8×10⁴, not less than 5×10⁴, not less than 1×10⁵, not less than 1.5×10⁵, not less than 3.1×10⁵, not less than 3.9×10⁵, not less than 5×10⁵ or not less than 6.3×10⁵, and particularly preferably not less than 1×10⁶. Alternatively, where x represents the ON/OFF current ratio, the lower limit of log₁₀x is preferably not less than 4, not less than 4.1, not less than 4.2, not less than 4.3, not less than 4.7, not less than 5, not less than 5.2, not less than 5.5, not less than 5.6, not less than 5.7 or not less than 5.8, and particularly preferably not less than 6. When the ON/OFF current ratio is large as just described, the difference between the current density in the low-resistance state and the current density in the high-resistance state (i.e., the ON/OFF current ratio) is large. Thus, the material can obtain an excellent OTS effect. The upper limit of the ON/OFF current ratio is not particularly limited, but may be, for example, not more than 2×10¹⁰, not more than 1×10⁹, not more than 1×10⁸ or particularly not more than 1×10⁷. The upper limit of the value of log₁₀x is preferably not more than 10.3, more preferably not more than 9, even more preferably not more than 8, and particularly preferably not more than 7.

In the variable-resistance material according to the present invention, the threshold voltage is preferably within a range of 0.5 V to 10 V. More specifically, the upper limit of the threshold voltage is preferably not more than 10V, more preferably not more than 8 V, even more preferably not more than 6 V, and particularly preferably not more than 5 V. When the threshold voltage is within the above range, a switch element or the like can be driven by less energy. The lower limit of the threshold voltage is not particularly limited, but may be not less than 0.5 V, not less than 0.8 V, not less than 1 V, not less than 1.2 V or particularly not less than 1.5 V.

The OFF current density, the ON current density, the ON/OFF current ratio, and the threshold voltage can be determined in the following manners. First, a 0 V to 10 V voltage is applied to a switch element to measure the values of current that flows through the switch element and the threshold voltage. The type of voltage to be applied in this case is, for example, a DC voltage, an AC voltage or a pulsed voltage, and is not limited, but the measurement is preferably conducted using a pulsed voltage from the viewpoint of preventing heat storage of the switch element. The threshold voltage can be defined as a voltage value at the time the electrical resistance value of the switch element rapidly changes from a high-resistance state to a low-resistance state. The OFF current density can be defined as a value obtained by dividing a value (OFF current value) of a current that flows through the switch element upon application of one-half the threshold voltage thereto by the contact area of the switch element with a first electrode or a second electrode. The ON current density can be defined as a value obtained by dividing a value (ON current value) of a current that flows through the switch element upon application of a voltage not less than the threshold voltage thereto by the contact area of the switch element with the first electrode or the second electrode. The ON/OFF current ratio can be determined by dividing the ON current value by the OFF current value. In the case where the contact area of the switch element with the first electrode is the same as the contact area of the switch element with the second electrode, the current density can be determined using the contact area with the first electrode or the second electrode as described above. On the other hand, in the case where the contact area of the switch element with the first electrode is different from the contact area of the switch element with the second electrode, the current density can be determined using a smaller one of both the contact areas.

In the variable-resistance material according to the present invention, the upper limit of the carrier mobility is preferably not more than 5×10⁻³ cm²/Vs, more preferably not more than 4.5×10⁻³ cm²/Vs, even more preferably not more than 4×10⁻³ cm²/Vs, still even more preferably not more than 3.5×10⁻³ cm²/Vs, and particularly preferably not more than 3×10⁻³ cm²/Vs. When the carrier mobility meets the above value, the OFF current density can be easily decreased. Therefore, the ON/OFF current ratio can be easily increased. The lower limit of the carrier mobility is not particularly limited, but may be, for example, not less than 1×10⁻⁸ cm²/Vs, 1×10⁻⁷ cm²/Vs or not less than 1×10⁻⁶ cm²/Vs. The carrier mobility can be measured using a resistivity/Hall measurement system.

The variable-resistance material according to the present invention contains Te. Te is a constituent of the variable-resistance material and an essential component that provides OTS characteristics. The content of Te is preferably 40% to 90%. More specifically, the lower limit of the content of Te is preferably not less than 40%, not less than 42%, not less than 47%, not less than 50%, more than 50%, not less than 51%, not less than 53%, not less than 55%, not less than 60%, not less than 61%, not less than 65%, not less than 67% or not less than 70%, and particularly preferably not less than 71%. The upper limit of the content of Te is preferably not more than 90%, not more than 89%, not more than 85%, not more than 82.5%, not more than 80% or not more than 75%, and particularly preferably not more than 72.5%. If the content of Te is too small, the amorphous state is likely to be unstable. In addition, the OTS characteristics are difficult to obtain. If the content of Te is too large, the amorphous state is likely to be unstable. In addition, the carrier mobility becomes excessively high and the OFF current density is likely to be large.

The variable-resistance material according to the present invention may contain components other than Te. For example, the variable-resistance material preferably contains, in terms of atomic %, 0.1% to 50% Ge and 40% to 90% Te. The variable-resistance material may contain components other than Ge and Te.

Ge is a component that stabilizes the amorphous state of the variable-resistance material. The content of Ge is preferably 0.1% to 50%. More specifically, the lower limit of the content of Ge is preferably not less than 0.1%, not less than 1%, not less than 3%, not less than 5%, not less than 7%, not less than 10% or not less than 11%, and particularly preferably not less than 13%. The upper limit of the content of Ge is preferably not more than 50%, more preferably not more than 40%, even more preferably not more than 30%, and particularly preferably not more than 20%. If the content of Ge is too small, the amorphous state is likely to be unstable. If the content of Ge is too large, the OTS characteristics are difficult to obtain. In addition, the production cost is likely to increase.

The lower limit of the content of Ge+Te (the total content of Ge and Te) is preferably not less than 41%, not less than 45%, not less than 50%, not less than 60%, not less than 65%, not less than 70% or not less than 75%, and particularly preferably not less than 80%. The upper limit of the content of Ge+Te is preferably not more than 99%, more preferably not more than 98%, even more preferably not more than 97%, and particularly preferably not more than 95%. If the content of Ge+Te is too small, the amorphous state is likely to be unstable. In addition, the OTS characteristics are difficult to obtain. If the content of Ge+Te is too large, the OTS characteristics are difficult to obtain.

Si, Al, Ga, Sn, Bi, Cu, Ag, Zn, Y, In, Ca, and Mg are components that stabilize the amorphous state of the variable-resistance material. In addition, these components are those that decrease the OFF current density and thus can easily increase the ON/OFF current ratio. Therefore, in the variable-resistance material according to the present invention, the content of Si+Al+Ga+Sn+Bi+Cu+Ag+Zn+Y+In+Ca+Mg (the total content of Si, Al, Ga, Sn, Bi, Cu, Ag, Zn, Y, In, Ca, and Mg) is preferably 1% to 59%. More specifically, the lower limit of the content of Si+Al+Ga+Sn+Bi+Cu+Ag+Zn+Y+In+Ca+Mg is preferably not less than 1% and particularly preferably not less than 2%. The upper limit of the content of Si+Al+Ga+Sn+Bi+Cu+Ag+Zn+Y+In+Ca+Mg is preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%. The content just described may be restated as follows: The variable-resistance material contains at least one of components selected from among Si, Al, Ga, Sn, Bi, Cu, Ag, Zn, Y, In, Ca, and Mg. If the content of these components is too small, the above effects are difficult to obtain. If the content of these components is too large, the amorphous state is likely to be unstable. In addition, the OTS characteristics are difficult to obtain. The lower limit of the content of each component of Si, Al, Ga, Sn, Bi, Cu, Ag, Zn, Y, In, Ca, and Mg is preferably not less than 0%, more preferably over 0%, even more preferably not less than 0.1%, still even more preferably not less than 0.5%, yet still even more preferably not less than 1%, and particularly preferably not less than 2%. The upper limit of the content of each component of Si, Al, Ga, Sn, Bi, Cu, Ag, Zn, Y, In, Ca, and Mg is preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%.

Among the above-mentioned components, Ga and Ag are components that decrease the carrier mobility and easily decrease the OFF current density, and therefore particularly contribute to increasing the ON/OFF current ratio. In addition, these components are also those that particularly easily stabilize the amorphous state. The lower limit of the content of Ga+Ag (the total content of Ga and Ag) is preferably not less than 0%, over 0%, not less than 0.1%, not less than 0.5%, not less than 1%, not less than 2% or not less than 3%, and particularly preferably not less than 5%, and the upper limit of the content of Ga+Ag is preferably not more than 59%, not more than 58%, not more than 55%, not more than 50%, not more than 45%, not more than 40%, not more than 35%, not more than 30%, not more than 25%, not more than 20%, not more than 15%, not more than 14%, not more than 13% or not more than 10%, and particularly preferably not more than 9%. If the content of Ga+Ag is too large, the amorphous state is likely to be unstable.

Particularly, from the viewpoint of decreasing the OFF current density, the lower limit of Ga/(Ga+Ag) is preferably not less than 0.1 and particularly preferably not less than 0.2, and the upper limit of Ga/(Ga+Ag) is preferably not more than 1.2, more preferably less than 1.2, and particularly preferably not more than 1.1. Herein, Ga/(Ga+Ag) is a value of the content of Ga divided by the total content of Ga and Ag.

Particularly, from the viewpoint of increasing the number of cycles to be described later, the lower limit of Ag/(Ga+Ag) is preferably not less than 0.1 and particularly preferably not less than 0.2, and the upper limit of Ag/(Ga+Ag) is preferably not more than 1.2, more preferably less than 1.2, and particularly preferably not more than 1.1. Herein, Ag/(Ga+Ag) is a value of the content of Ag divided by the total content of Ga and Ag.

Sb is a component likely to make the amorphous state unstable at high temperatures. Therefore, the content of Sb is preferably 0% to less than 5%. More specifically, the upper limit of the content of Sb is preferably less than 5%, more preferably not more than 4%, even more preferably not more than 3%, and still even more preferably not more than 2%, and the variable-resistance material is particularly preferably substantially free of Sb. Herein, “substantially free of” means that no amount of the relevant component is deliberately contained in the source material, and is not intended to exclude even the incorporation thereof in impurity level. Objectively, this means that the content of the component is less than 0.1%.

Se is a component that easily stabilizes the amorphous state of the variable-resistance material. The upper limit of the content of Se is preferably not more than 58%, more preferably not more than 55%, and particularly preferably not more than 50%. The lower limit of the content of Se is preferably not less than 0%, more preferably not less than 1%, even more preferably not less than 5%, still even more preferably not less than 10%, and particularly preferably not less than 20%. If the content of Se is too large, the amorphous state is likely to be unstable. Furthermore, Se is a toxic component. Therefore, from the viewpoint of reducing the burden on the environment, the upper limit of the content of Se is preferably not more than 40%, more preferably not more than 30%, even more preferably not more than 20%, and still even more preferably not more than 10%, and the variable-resistance material is particularly preferably substantially free of Se.

As is a component that easily stabilizes the amorphous state of the variable-resistance material. However, because As is a toxic component, the content of As is preferably 0% to 30% from the viewpoint of reducing the burden on the environment. More specifically, the upper limit of the content of As is preferably not more than 30%, more preferably not more than 25%, even more preferably not more than 20%, still even more preferably not more than 10%, yet still even more preferably not more than 5%, and further even more preferably not more than 3%, and the variable-resistance material is particularly preferably substantially free of As.

The variable-resistance material according to the present invention is preferably substantially free of Sb, Se, and As. Thus, the burden on the environment can be more easily reduced.

If the content of B, C, N, F, Cl, Br, and I is too large, the amorphous state is likely to be unstable. In addition, the weather resistance is likely to decrease. Therefore, the upper limit of the content of B+C+N+F+Cl+Br+I (the total content of B, C, N, F, Cl, Br, and I) is preferably not more than 50%, not more than 45%, not more than 40%, not more than 35%, not more than 30%, not more than 25%, not more than 20%, not more than 15%, not more than 14%, not more than 12%, not more than 10%, not more than 8% or not more than 6%, and particularly preferably not more than 5%. Furthermore, the upper limit of the content of each component of B, C, N, F, Cl, Br, and I is preferably not more than 50%, not more than 45%, not more than 40%, not more than 35%, not more than 30%, not more than 25%, not more than 20%, not more than 15%, not more than 14%, not more than 12%, not more than 10%, not more than 8% or not more than 6%, and particularly preferably not more than 5%. However, from the viewpoint of increasing the crystallization temperature, the variable-resistance material may contain B, C, N, F, Cl, Br, and I in a total amount of not less than 0%, not less than 1% or particularly not less than 2%.

If the content of P, Cr, Mn, Ti, and Fe is too large, the amorphous state is likely to be unstable. Therefore, the content of P+Cr+Mn+Ti+Fe (the total content of P, Cr, Mn, Ti, and Fe) is preferably 0% to 10%. More specifically, the upper limit of the content of P+Cr+Mn+Ti+Fe is preferably not more than 10%, more preferably not more than 5%, even more preferably not more than 1%, still even more preferably less than 1%, and yet still even more preferably not more than 0.1%, and the variable-resistance material is particularly preferably substantially free of these components. If the content of these components is too large, the amorphous state is likely to be unstable. The content of each component of P, Cr, Mn, Ti, and Fe is preferably 0% to 10%. More specifically, the upper limit of the content of each component of P, Cr, Mn, Ti, and Fe is preferably not more than 10%, more preferably not more than 5%, even more preferably not more than 1%, still even more preferably less than 1%, and yet still even more preferably not more than 0.1%, and the variable-resistance material is particularly preferably substantially free of each of these components.

From the viewpoint of reducing the burden on the environment, the variable-resistance material is preferably substantially free of Cd, Tl, and Pb.

The variable-resistance material according to the present invention preferably has an oxygen content of less than 1 atomic %. More specifically, the upper limit of the oxygen content is, in terms of atomic %, preferably not more than 0.8%, not more than 0.5%, not more than 0.3%, not more than 0.1%, not more than 0.09% or not more than 0.05%, and particularly preferably not more than 0.02%. If the oxygen content is too large, the ON current density is likely to decrease and, additionally, the threshold voltage is likely to be high. From the viewpoint of the cost for refining the source material, the lower limit of the oxygen content is, in terms of atomic %, preferably not less than 1×10⁻⁶%, more preferably not less than 1×10⁻⁵%, even more preferably not less than 5×10⁻⁵%, still even more preferably not less than 1×10⁻⁴%, and particularly preferably not less than 2×10⁻⁴%.

The composition of the variable-resistance material can be evaluated using the energy dispersive X-ray spectroscopy (EDX), an electron probe microanalyzer (EPMA), the X-ray fluorescence analysis (XRF) or so on. The evaluation by EDX may be made by an analyzer TEM-EDX or SEM-EDX attached to a transmission electron microscope (TEM) or a scanning electron microscope (SEM). The oxygen content can be evaluated using, for example, the inert gas fusion-infrared absorption method.

In the variable-resistance material according to the present invention, the crystallization temperature Tx is preferably not lower than 150° C., more preferably not lower than 160° C., and particularly preferably not lower than 170° C. When the crystallization temperature Tx meets the above value, crystallization due to exotherm caused at switching is less likely to occur and the number of cycles to be described later can be more easily increased. The upper limit of the crystallization temperature Tx is not particularly limited, but may be, for example, not higher than 500° C., not higher than 450° C. or particularly not higher than 400° C.

The crystallization temperature Tx of the variable-resistance material can be evaluated using the differential thermal analysis (DTA) or the differential scanning calorimetry (DSC). Alternatively, the crystallization temperature Tx may be evaluated by, in the measurement of the electrical resistance by the two-terminal method, determining the dependence of electrical resistance on temperature and regarding the temperature at which the electrical resistance rapidly drops as the crystallization temperature Tx. Still alternatively, an obtained variable-resistance material may be heat-treated at a predetermined temperature and the point at which a crystallization peak appears by XRD may be evaluated as the crystallization temperature Tx. It is preferred that the crystallization temperature Tx evaluated by any one of the above-described methods meets any above-described preferred value of crystallization temperature Tx. It is particularly preferred that the crystallization temperature Tx evaluated based on the dependence of electrical resistance on temperature meets any above-described preferred value of crystallization temperature Tx.

Since the variable-resistance material according to the present invention has a stable amorphous state, it can increase the number of cycles when used as a switch element. In other words, the ON/OFF current ratio can be maintained even when turning-on and turning-off are repeated. Specifically, the lower limit of the number of cycles (the number of repetitions of switching between ON and OFF current until the ON/OFF current ratio reaches 10% of its initially measured value) is preferably not less than 5×10², more preferably not less than 1×10³, and particularly preferably not less than 1×10⁴. If the number of cycles is too small, the variable-resistance material is difficult to use as a switch element. The upper limit of the number of cycles is not particularly limited, but may be, for example, not more than 1×10¹⁰, not more than 1×10⁹, not more than 1×10⁸ or not more than 1×10⁷.

The variable-resistance material according to the present invention is preferably used as a thin film (a variable-resistance film). The thin film (variable-resistance film) can be particularly suitably used as a switch layer or a switch memory layer which will be described later. However, the form of the variable-resistance material is not limited to the thin film.

The thickness of the thin film (variable-resistance film) is preferably 1 nm to 300 nm. More specifically, the lower limit of the thickness of the variable-resistance film is preferably not less than 1 nm, more preferably not less than 2 nm, even more preferably not less than 5 nm, still even more preferably not less than 10 nm, yet still even more preferably not less than 30 nm, and particularly preferably more than 50 nm, and the upper limit of the thickness of the variable-resistance film is preferably not more than 300 nm, more preferably not more than 200 nm, and particularly preferably not more than 100 nm. If the film thickness is too small, the current value (OFF current) in a high-resistance state tends to be high. If the film thickness is too large, the threshold voltage is likely to be large.

A material for a switch element according to the present invention is preferably made of the above-described variable-resistance material according to the present invention. A switch layer according to the present invention is preferably made of the above-described variable-resistance material according to the present invention. Since, as described previously, the variable-resistance material according to the present invention has excellent OTS characteristics, it can be suitably used as a switch layer and a material for a switch element.

The variable-resistance material according to the present invention can be produced, for example, in the following manner. First, raw materials are formulated to give a desired composition. Next, the formulated raw materials are put into a quartz glass ampule evacuated while being heated, and the ampule is sealed with an oxygen burner while being evacuated. Next, the sealed quartz glass ampule is held at about 650° C. to about 1000° C. for 6 hours to 12 hours. Thereafter, the ampule is rapidly cooled to room temperature. Thus, a bulk variable-resistance material can be obtained.

Elemental materials (such as Ge, Ga, Si, Te, Ag or I) may be used as raw materials or compound materials (such as GeTe₄, Ga₂Te₃ or AgI) may be used as raw materials. Alternatively, these types of materials may be used in combination.

By a PVD (physical vapor deposition) process using the obtained variable-resistance material as a target, a thin film (a variable-resistance film) having the above-described composition can be formed.

Alternatively, by a multi-sputtering process using pure elemental M targets (Ge, Te, Sb, Si, Al, Ga, Sn, Bi, Cu, Ag, Zn, Y, In, Ca, and Mg) as targets, a binary alloy target as a target or a ternary or higher alloy target as a target, a thin film (a variable-resistance film) having the above-described composition can be formed by appropriately controlling the deposition output to adjust the components.

The method for producing a thin film is not particularly limited and the sputtering process, vacuum evaporation or ion plating can be used as the PVD process. Alternatively, the CVD (chemical vapor deposition) process, the ALD (atomic layer deposition) process or others may be selected as the method for producing a thin film. Among others, the sputtering process is preferably used because the composition and the film thickness can be easily controlled.

### <Switch Element>

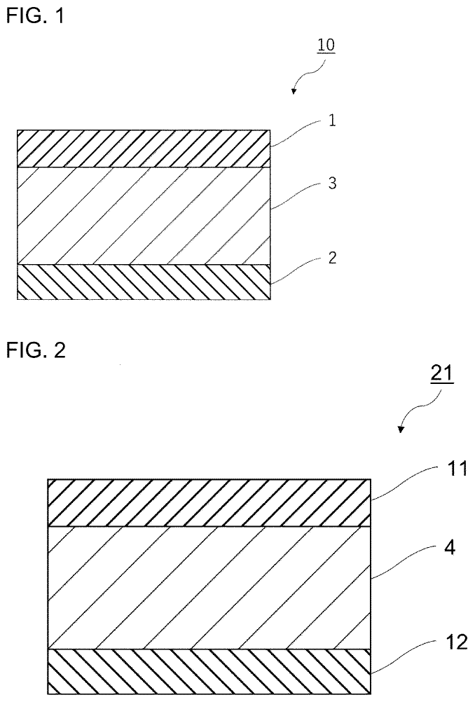

FIG. 1 is a schematic cross-sectional view of a switch element according to one embodiment of the present invention. A switch element 10 includes a first electrode 1, a second electrode 2, and a switch layer 3 disposed on a principal surface of the first electrode 1. The second electrode 2 is disposed opposite to the first electrode 1. In this embodiment, the switch layer 3 is disposed between the first electrode 1 and the second electrode 2. In other words, the switch element 10 according to this embodiment includes the switch layer 3 and the first electrode 1 disposed on the switch layer 3. In still other words, the switch element 10 according to this embodiment preferably includes the second electrode 2 opposed to the first electrode 1 with the switch layer 3 in between. In this case, the switch layer 3 is preferably made of a variable-resistance material which contains Te and in which when its current density upon application of one-half the threshold voltage thereto is defined as an OFF current density, the OFF current density is not more than 3.1×10² A/cm².

The switch element 10 according to this embodiment can be suitably used in a cross-point memory device or a BiCS (bit-cost scalable) memory device which will be described later. In the case of a BiCS memory device, the switch element 10 according to this embodiment preferably has a structure in which the first electrode 1 is disposed on the outer periphery of the switch layer 3 and the second electrode 2 is disposed on the inner periphery of the switch layer 3.

An inorganic material may be used for the first electrode 1 and the second electrode 2. Examples that can be used as the inorganic material include a metallic material and a ceramic material. For example, the material for the first electrode 1 and the second electrode 2 is preferably at least one selected from among tungsten, titanium, copper, platinum, tungsten nitride, and titanium nitride. Tungsten, titanium, copper or platinum is preferred as the metallic material. Tungsten nitride or titanium nitride is preferred as the ceramic material.

The thicknesses of the first electrode 1 and the second electrode 2 can be appropriately designed. For example, the upper limit of the thickness of each of the first electrode 1 and the second electrode 2 is preferably not more than 200 nm, more preferably not more than 100 nm, even more preferably not more than 80 nm, still even more preferably not more than 60 nm, and particularly preferably not more than 50 nm. Smaller thickness of each of the first electrode 1 and the second electrode 2 is more advantageous to increasing the capacity of a memory device. The lower limit of the thickness of each of the first electrode 1 and the second electrode 2 is, for example, preferably not less than 1 nm and particularly preferably not less than 2 nm.

The upper limit of the area of each of the first electrode 1 and the second electrode 2 is preferably not more than 1000000 nm², not more than 562500 nm², not more than 250000 nm², not more than 62500 nm², not more than 10000 nm², not more than 6400 nm² or not more than 2500 nm², and particularly preferably not more than 1600 nm². The lower limit of the area of each of the first electrode 1 and the second electrode 2 is not particularly limited, but may be not less than 1 nm² or particularly not less than 2 nm² from the viewpoint of production cost. Furthermore, the upper limit of the contact area of the first electrode 1 with the switch layer 3 or the contact area of the second electrode 2 with the switch layer 3 is preferably not more than 1000000 nm², not more than 562500 nm², not more than 250000 nm², not more than 62500 nm², not more than 10000 nm², not more than 6400 nm² or not more than 2500 nm², and particularly preferably not more than 1600 nm². This makes it more advantageous to increasing the capacity of a memory device. The lower limit of the contact area of the first electrode 1 with the switch layer 3 or the contact area of the second electrode 2 with the switch layer 3 is not particularly limited, but may be not less than 1 nm² or particularly not less than 2 nm² from the viewpoint of production cost. As for the contact areas of electrodes with the switch layer 3, it is sufficient that at least one of the contact area of the first electrode 1 with the switch layer 3 and the contact area of the second electrode 2 with the switch layer 3 meets the above value, and it is more preferred that both the contact areas meet the above value.

The switch layer 3 is made of the variable-resistance material according to the present invention and, therefore, exhibits the OTS characteristics. More specifically, the switch layer 3 is preferably formed of a thin film (a variable-resistance film). The switch layer 3 changes its resistance state with applied voltage. Specifically, when a voltage not less than the threshold voltage is applied to the switch layer 3, the switch layer 3 becomes a low-resistance state (an ON state). On the other hand, when one-half the threshold voltage is applied to the switch layer 3, the switch layer 3 becomes a high-resistance state (an OFF state). In this embodiment, the switch layer 3 is amorphous and does not undergo any phase change due to the application of voltage. In other words, even when voltage is applied to the switch layer 3, the switch layer 3 does not change the phase to crystalline.

The switch layer 3 is disposed in contact with at least one of the electrodes. In other words, the switch layer 3 is preferably disposed on the first electrode 1. In still other words, the first electrode 1 is preferably disposed on the switch layer 3. Furthermore, the switch element 10 preferably includes the second electrode 2 opposed to the first electrode 1 with the switch layer 3 in between.

The thickness of the switch layer 3 can be appropriately designed according to a desired threshold voltage. The upper limit of the thickness of the switch layer 3 is, for example, preferably not more than 300 nm, more preferably not more than 200 nm, and particularly preferably not more than 100 nm. If the thickness is too large, the threshold voltage is likely to be excessively large. The lower limit of the thickness of the switch layer 3 is, for example, preferably not less than 1 nm, more preferably not less than 2 nm, even more preferably not less than 5 nm, still even more preferably not less than 10 nm, yet still even more preferably not less than 30 nm, and particularly preferably more than 50 nm.

In the switch element 10, the ionicity r_{σ}′ and hybridization r_{π}⁻¹ of the switch layer 3 preferably satisfy respective desired values. More specifically, the ionicity r_{σ}′ of the switch layer 3 is preferably not less than 0.05. The upper limit of the ionicity r_{σ}′ is not particularly limited, but may be, for example, not more than 0.30, not more than 0.25 or particularly not more than 0.20. The hybridization r_{π}⁻¹ of the switch layer 3 is preferably not more than 2.0 and particularly preferably not more than 1.9. The lower limit of the hybridization r_{π}⁻¹ is not particularly limited, but may be, for example, not less than 1.0, not less than 1.1, not less than 1.2 or particularly not less than 1.3. When the ionicity r_{σ}′ and hybridization r_{π}⁻¹ of the switch layer 3 satisfy the above values, the OFF current density can be decreased while the stability of an amorphous state can be maintained. The ionicity r_{σ}′ and hybridization r_{π}⁻¹ of the switch layer 3 can be calculated from the following formulas 1 and 2, which are described in Non-Patent Literature 1 (NPL 1). In the following formulas, rₛ and rₚ represent the respective orbital radiuses of s and p and nᵢ and nⱼ represent the respective numbers of atoms per formula unit of a chemical species i (anion) and a chemical species j (cation).

$$\begin{matrix}[ Math . 1 ] & \\ {r}_{σ}^{′} = ( \frac{{\sum }_{i} {n}_{i} {r}_{p , i}}{{\sum }_{i} {n}_{i}} ) - ( \frac{{\sum }_{j} {n}_{j} {r}_{p , j}}{{\sum }_{j} {n}_{j}} ) & Formula ( 1 )\end{matrix}$$

$$\begin{matrix}[ Math . 2 ] & \\ {r}_{π}^{- 1} = {[ ( \frac{{\sum }_{i} {n}_{i} ( {r}_{p , i} - {r}_{s , i} )}{{\sum }_{i} {n}_{i}} ) + ( \frac{{\sum }_{j} {n}_{j} ( {r}_{p , j} - {r}_{s , j} )}{{\sum }_{j} {n}_{j}} ) ]}^{- 1} & Formula ( 2 )\end{matrix}$$

The switch element 10 according to this embodiment preferably increases the carrier activation energy with increase in applied voltage. For example, where a (eV) represents the carrier activation energy of the switch element 10 upon application of an applied voltage of 0.15 V to the switch layer 3 and b (eV) represents the carrier activation energy of the switch element 10 upon application of an applied voltage of 0.30 V to the switch layer 3, the switch element 10 preferably satisfies a/b<1. When the switch element 10 exhibits the above characteristics, even at a large applied voltage, the OFF current density is less likely to be high and the ON/OFF current ratio becomes large. Herein, the carrier activation energy refers to an energy necessary for electrons to transition to a conducting state and can be determined in the following manner. First, voltage is applied to the switch element 10 at different temperatures and the values of current in these cases are measured. The range of temperatures and range of applied voltages in these cases are not limited, but, for example, the temperature may be 30° C. to 80° C. and the applied voltage may be 0 V to 30 V. Next, from the current value at an arbitrary voltage value and the temperature at the measurement of the current value, the carrier activation energy can be calculated using the following formula (3). In the formula, I represents the current, Eₐ represents the carrier activation energy, k represents the Boltzmann constant, I represents the absolute temperature, and C represents the constant.

$$\begin{matrix}[ Math . 3 ] & \\ ln ( I ) = \frac{{E}_{a}}{kT} + C & Formula ( 3 )\end{matrix}$$

The switch element 10 according to this embodiment preferably exhibits a tendency to increase the threshold voltage with the application of heat. For example, the threshold voltage of the switch element 10 at 80° C. is preferably not less than 1.05 times the threshold voltage at a room temperature of 25° C. and particularly preferably not less than 1.1 times the threshold voltage at 25° C. When the switch element 10 exhibits the above characteristics, even in a high-temperature state where the electron kinetic energy is large, the OFF current density is less likely to be high, a high ON/OFF current ratio is maintained even at high temperatures, and, thus, the switch element 10 exhibits excellent thermal resistance.

The switch element 10 according to this embodiment preferably increases the Schottky barrier height with increasing temperature. For example, the Schottky barrier height of the switch element 10 at 80° C. is preferably not less than 1.01 times the Schottky barrier height at 30° C. and particularly preferably not less than 1.02 times the Schottky barrier height at 30° C. When the switch element 10 exhibits the above characteristics, the transfer of carriers is prevented and, thus, the OFF current density can be decreased. Therefore, the ON/OFF current ratio can be easily increased. The Schottky barrier height φ_{B} can be calculated from the following formula (4). In the formula, Iₛ represents the saturated current, A represents the contact area, A* represents the Richardson constant, q represents the elementary electric charge, k represents the Boltzmann constant, and T represents the absolute temperature.

$$\begin{matrix}[ Math . 4 ] & \\ {I}_{S} = AA * exp ( - \frac{q {φ}_{B}}{kT} ) & Formula ( 4 )\end{matrix}$$

### <Memory Element>

FIG. 2 is a schematic cross-sectional view of a memory element according to one embodiment of the present invention. A memory element 21 includes a first electrode 11, a second electrode 12, and a switch memory layer 4 disposed on a principal surface of the first electrode 11. The second electrode 12 is disposed opposite to the first electrode 11. In this embodiment, the switch memory layer 4 is disposed between the first electrode 11 and the second electrode 12. In other words, the memory element 21 according to this embodiment includes the switch memory layer 4, the first electrode 11 disposed on one principal surface of the switch memory layer 4, and the second electrode 12 disposed on the other principal surface of the switch memory layer 4. The switch memory layer 4 is formed of a variable-resistance film.

An inorganic material may be used for the first electrode 11 and the second electrode 12. Examples that can be used as the inorganic material include a metallic material and a ceramic material. For example, tungsten, titanium, copper or platinum is preferably used as the metallic material. For example, tungsten nitride or titanium nitride is preferably used as the ceramic material.

The thicknesses of the first electrode 11 and the second electrode 12 can be appropriately designed. For example, the thickness of each of the first electrode 11 and the second electrode 12 is preferably not more than 200 nm, more preferably not more than 100 nm, even more preferably not more than 80 nm, still even more preferably not more than 60 nm, and particularly preferably not more than 50 nm. Smaller thickness of each of the first electrode 11 and the second electrode 12 is more advantageous to increasing the capacity of a memory device. The lower limit of the thickness of each of the first electrode 11 and the second electrode 12 is, for example, preferably not less than 1 nm and particularly preferably not less than 2 nm.

The memory element 21 is a variable-resistance memory element and includes a switch memory layer 4 having a memory function and a switch element function. For example, when a voltage not less than a predetermined voltage is applied to the switch memory layer 4, the switch memory element 4 can be changed to a low-resistance state LR1 and, thus, can record information therein. Furthermore, when the applied voltage to the switch memory layer 4 is gradually decreased from the low-resistance state LR1, the switch memory layer 4 is changed to a high-resistance state HR1 with the information recorded therein. When a readout voltage is applied to the switch memory layer 4 without doing a deletion operation of the memory, the switch memory layer 4 is further changed to a low-resistance state LR2. On the other hand, when a readout voltage is applied to the switch memory layer 4 in a high-resistance state with no information recorded or in a high-resistance state after the deletion operation is done, the switch memory layer 4 reaches a high-resistance state HR2. In these cases, when 1 and 0 is allocated to LR2 and HR2, respectively, information can be recorded. The method for operating is not limited to the above method. For example, when the applied voltage is changed to zero after the recording of information and a readout voltage is then applied, reaching LR2. On the other hand, when a readout voltage is applied after the deletion operation is done, reaching HR2. Therefore, when 1 and 0 is allocated to LR2 and HR2, respectively, information can be recorded.

The upper limit of the area of each of the first electrode 11 and the second electrode 12 is preferably not more than 1000000 nm², not more than 562500 nm², not more than 250000 nm², not more than 62500 nm², not more than 10000 nm², not more than 6400 nm² or not more than 2500 nm², and particularly preferably not more than 1600 nm². The lower limit of the area of each of the first electrode 11 and the second electrode 12 is not particularly limited, but may be not less than 1 nm² or particularly not less than 2 nm² from the viewpoint of production cost. Furthermore, the upper limit of the contact area of the first electrode 11 with the switch memory layer 4 or the contact area of the second electrode 12 with the switch memory layer 4 is preferably not more than 1000000 nm², not more than 562500 nm², not more than 250000 nm², not more than 62500 nm², not more than 10000 nm², not more than 6400 nm² or not more than 2500 nm², and particularly preferably not more than 1600 nm². This makes it more advantageous to increasing the capacity of a memory device. The lower limit of the contact area of the first electrode 11 with the switch memory layer 4 and/or the contact area of the second electrode 12 with the switch memory layer 4 is not particularly limited, but may be not less than 1 nm² or particularly not less than 2 nm² from the viewpoint of production cost. As for the contact areas of electrodes with the switch memory layer 4, it is sufficient that at least one of the contact area of the first electrode 11 with the switch memory layer 4 and the contact area of the second electrode 12 with the switch memory layer 4 meets the above value, and it is more preferred that both the contact areas meet the above value.

### <Memory Device>

### First Embodiment

A memory device according to this embodiment preferably includes a switch element and more preferably includes a switch element and a memory element. In the case where the memory device according to the present invention includes a switch element and a memory element, it is preferably formed of a laminate in which the switch element and the memory element are layered. More specifically, the memory device according to this embodiment is preferably a memory device including a laminate in which a switch element and a memory element are layered, wherein: the switch element includes a switch layer and a first electrode disposed on the switch layer; the switch layer is made of a variable-resistance material in which when a current density of the variable-resistance material upon application of one-half the threshold voltage thereto is defined as an OFF current density, the OFF current density is not more than 3.1×10² A/cm²; and the memory element is made of at least one of a variable-resistance memory element, a magnetoresistive memory element, a phase-change memory element, and a ferroelectric memory element.

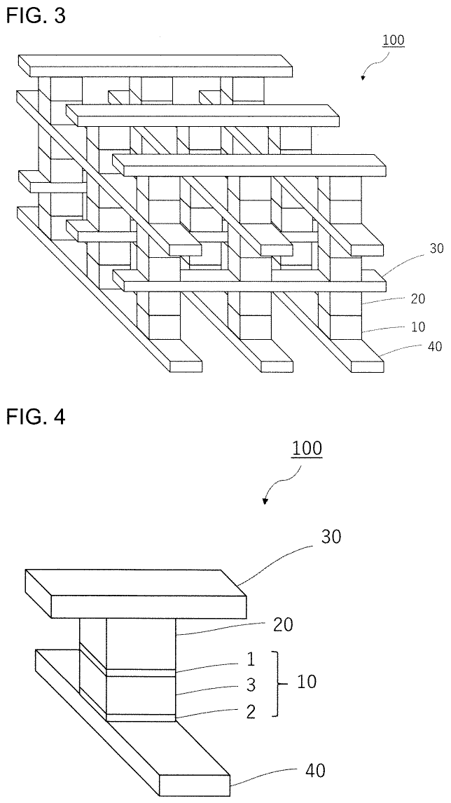

FIG. 3 is a schematic stereogram of a memory device according to a first embodiment of the present invention and FIG. 4 is a schematic partially enlarged stereogram of the memory device according to the first embodiment of the present invention. As shown in FIGS. 3 and 4, a memory device 100 includes switch elements 10, memory elements 20, word lines 30, and bit lines 40. The bit lines 40 are orthogonal to the word lines 30 in plan view. The switch elements 10 and the memory elements 20 are disposed at the intersections between the word lines 30 and the bit lines 40 in plan view. Accordingly, the memory device 100 according to this embodiment is a so-called cross-point memory device.

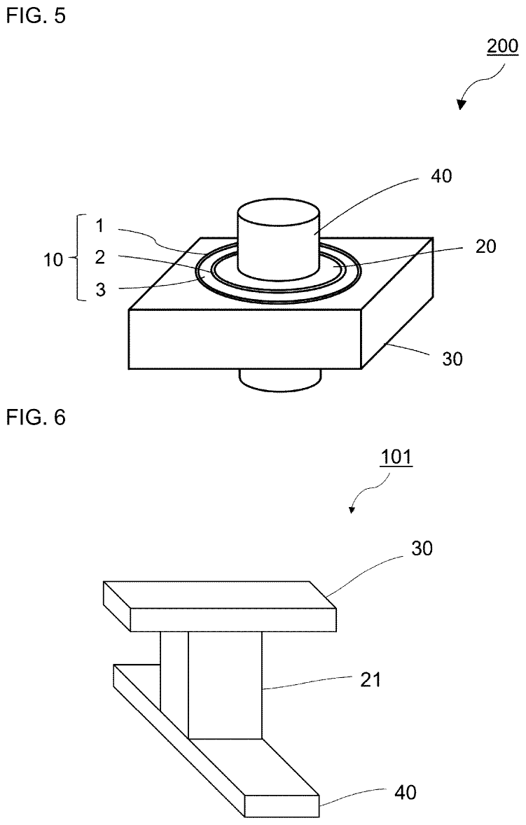

FIG. 5 is a schematic stereogram of a modification of the memory device according to the first embodiment of the present invention. A memory device 200 includes switch elements 10, memory elements 20, word lines 30, and bit lines 40. A bit line 40 is disposed through a through hole provided in a word line 30. Furthermore, a memory element 20 and a switch element 10 are disposed on the outer periphery of the bit line 40. The switch element 10 has a structure in which a first electrode 1 is disposed on the outer periphery of a switch layer 3 and a second electrode 2 is disposed on the inner periphery of the switch layer 3 and opposed to the first electrode 1 with the switch layer 3 in between. Accordingly, the memory device 200 according to this modification is a so-called BiCS memory device. As thus far described, the memory device according to the present invention is not limited to a cross-point memory device and may be various types of memory device.

The type of the memory element 20 that can be used is any type of memory element, including a variable-resistance memory element, a magnetoresistive memory element, a phase-change memory element, and a ferroelectric memory element. Hereinafter, a description will be given of preferred forms of each type of memory element.

The variable-resistance memory element includes a variable-resistance layer. More specifically, the variable-resistance memory element preferably includes a laminate in which a variable-resistance layer is sandwiched between an upper electrode and a lower electrode. The variable-resistance layer is preferably made of a metal oxide material, a metal nitride material or a chalcogenide material. The metal oxide material is, for example, preferably at least one selected from among NiOₓ, NbOₓ, TiOₓ, TaOₓ, HfOₓ, ZrOₓ, MoOₓ, WOₓ, and Pr₁₋ₓCaₓMnO₃ (PCMO). The metal nitride material is, for example, preferably at least one selected from among SiNₓ, AlNₓ, ZrNₓ, NiNₓ, CuNₓ, and CrNₓ. The chalcogenide material is, for example, preferably at least one selected from among Ge—Te, Sb—Te, Ge—Sb—Te, Si—Sb—Te, Ge—Ga—Te, In—Sb—Te, Ge—Se—As, and Ge—Se—As—Te. Alternatively, the variable-resistance layer may be formed of carbon nanotubes.

In the variable-resistance memory element, the upper electrode and/or the lower electrode are preferably made of at least one selected from among tungsten, titanium, copper, platinum, tungsten nitride, and titanium nitride. Tungsten, titanium, copper or platinum is preferred as the metallic material. Tungsten nitride or titanium nitride is preferred as the ceramic material.

The magnetoresistive memory element includes a laminate (a TMR element) in which an insulator layer is sandwiched between ferromagnetic layers. The insulator layer is made of an insulating material and is, for example, preferably made of at least one selected from among MgO, Cao, SrO, and Al₂O₃. The thickness of the insulator layer is preferably 0.1 nm to 3 nm. The ferromagnetic layer is made of a ferromagnetic material and is, for example, preferably made of at least one selected from among CoFeB, FeB, NiFe, MnIr, Fe, CoPt, CoNi, Co, Ni, Pt, Ni, and Mn.

The ferroelectric memory element includes a ferroelectric layer. More specifically, the ferroelectric memory element preferably includes a laminate in which a ferroelectric layer is sandwiched between an upper electrode and a lower electrode. The ferroelectric layer is preferably made of a ferroelectric material containing hafnium oxide and, for example, preferably made of hafnium oxide doped with at least one selected from among Si, Zr, Ge, Gd, La, Y, and Yb. Alternatively, the ferroelectric layer may be made of at least one selected from among lead zirconate titanate (PZT), strontium bismuth tantalate (SBT), and bismuth ferrite (BFO).

The phase-change memory element is a memory layer formed of a phase-change material. More specifically, the phase-change memory element preferably includes a laminate in which a phase-change layer is sandwiched between an upper electrode and a lower electrode. The phase-change layer is preferably made of a chalcogenide material. The chalcogenide material is, for example, preferably at least one selected from among Ge—Te, Sb—Te, Ge—Sb—Te, Si—Sb—Te, Ge—Ga—Te, In—Sb—Te, Cu—Ge—Te, Cr—Ge—Te, Mn—Te, Ge—Se—As, and Ge—Se—As—Te.

### Second Embodiment

The memory device according to the present invention is not limited to the structure that includes a switch layer and a memory element separately. For example, the memory device according to the present invention may have a structure that includes a switch element only. In this case, the switch element can function as a switch element and a memory element. For example, a memory device according to this embodiment preferably includes a variable-resistance memory element (a memory element 21) having the above-described memory function and switch element function. Since, in this embodiment, a variable-resistance memory element having a memory function and a switch element function is used, information can be recorded in the memory element even without a switch element. However, the memory device according to this embodiment may include any type of switch element.

FIG. 6 is a schematic stereogram of a memory device according to a second embodiment of the present invention. As shown in FIG. 6, a memory device 101 includes a memory element 21, a word line 30, and a bit line 40. The bit line 40 is orthogonal to the word line 30 in plan view. The memory element 21 is disposed at the intersection between the word line 30 and the bit line 40 in plan view. Accordingly, the memory device 101 according to this embodiment is a so-called cross-point memory device.

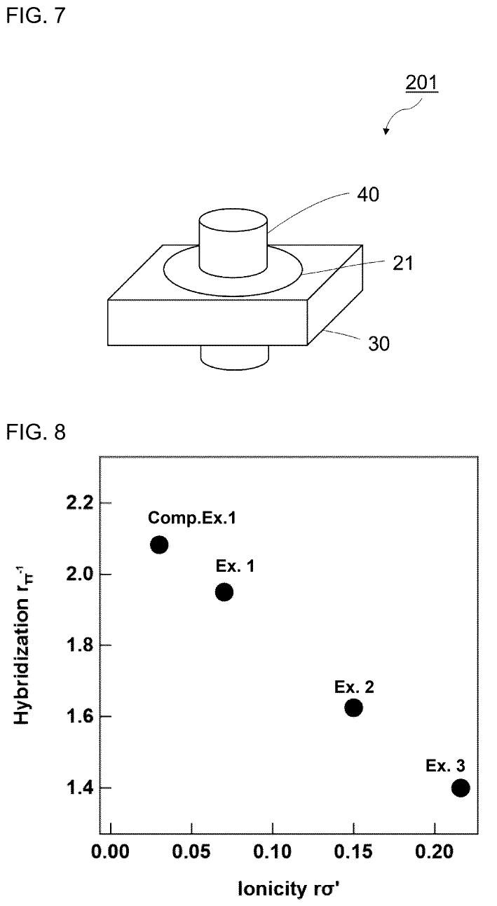

FIG. 7 is a schematic stereogram of a modification of the memory device according to the second embodiment of the present invention. As shown in FIG. 7, a memory device 201 includes a memory element 21, a word line 30, and a bit line 40. The bit line 40 is disposed through a through hole provided in the word line 30. The memory element 21 is disposed on the outer periphery of the bit line 40. Accordingly, the memory device 201 according to this embodiment is a so-called BiCS memory device. As thus far described, also in this embodiment, the memory device is not limited to a cross-point memory device and may be various types of memory device.

### EXAMPLES

Hereinafter, the present invention will be described with reference to examples, but the present invention is not limited to these examples.

TABLE 1

| | | | | | | | | | Comp. |
|---|---|---|---|---|---|---|---|---|---|
| | | Ex. 1 | Ex. 2 | Ex. 3 | Ex. 4 | Ex. 5 | Ex. 6 | Ex. 7 | Ex. 1 |
| Variable- | Te | 76.9 | 75.0 | 78.9 | 77.1 | 71.1 | 71.1 | 72.0 | 83.3 |
| Resistance | Ge | 15.4 | 15.0 | 15.8 | 12.9 | 14.2 | 14.2 | 18.0 | 16.7 |
| Material | Ga | 7.7 | 5.0 | 0.0 | 5.0 | 10.0 | 4.7 | 5.0 | 0.0 |
| (atomic %) | Ag | 0.0 | 5.0 | 5.3 | 5.0 | 4.7 | 10.0 | 5.0 | 0.0 |

| | | | | | | | | |
|---|---|---|---|---|---|---|---|---|
| Ge + Te | 92.3 | 90.0 | 94.7 | 90.0 | 85.3 | 85.3 | 90.0 | 100.0 |
| Ge/Te | 0.2 | 0.2 | 0.2 | 0.2 | 0.2 | 0.2 | 0.3 | 0.2 |
| Ga + Ag | 7.7 | 10.0 | 5.3 | 10.0 | 14.7 | 14.7 | 10.0 | 0.0 |
| Ga/(Ga + Ag) | 1.0 | 0.5 | 0.0 | 0.5 | 0.7 | 0.3 | 0.5 | — |
| Ag/(Ga + Ag) | 0.0 | 0.5 | 1.0 | 0.5 | 0.3 | 0.7 | 0.5 | — |
| Oxygen Content | 0.0004 | 0.0011 | 0.0042 | 0.0052 | 0.0076 | 0.0104 | 0.0027 | 0.0038 |
| (atomic %) | | | | | | | | |

TABLE 2

| | | | | | | | | Comp. |
|---|---|---|---|---|---|---|---|---|
| | Ex. 1 | Ex. 2 | Ex. 3 | Ex. 4 | Ex. 5 | Ex. 6 | Ex. 7 | Ex. 1 |
| OFF Current | 4.59 × 10¹ | 1.27 × 10⁰ | 2.55 × 10² | 3.46 × 10¹ | 1.70 × 10² | 6.37 × 10¹ | 3.92 × 10⁰ | 3.57 × 10² |
| Density J_{off} | | | | | | | | |
| (A/cm²) | | | | | | | | |
| ON Current | 4.59 × 10⁶ | 5.81 × 10⁶ | 4.60 × 10⁶ | 9.17 × 10⁶ | 6.11 × 10⁶ | 5.10 × 10⁶ | 5.61 × 10⁶ | 3.16 × 10⁶ |
| Density Jₒₙ | | | | | | | | |
| (A/cm²) | | | | | | | | |
| ON/OFF Current | 5.1 | 6.6 | 4.3 | 5.4 | 4.6 | 4.9 | 6.2 | 3.9 |
| Ratio log₁₀x | | | | | | | | |
| Threshold Voltage | 3.5 | 1.9 | 3.0 | 2.9 | 2.6 | 2.8 | 2.7 | 2.2 |
| Vth | | | | | | | | |
| (V) | | | | | | | | |
| Carrier Mobility | 2.1 × 10⁻⁴ | 8.7 × 10⁻⁵ | 2.6 × 10⁻³ | 1.6 × 10⁻⁴ | 7.5 × 10⁻⁴ | 2.2 × 10⁻⁴ | 1.1 × 10⁻⁴ | 5.1 × 10⁻³ |
| (cm²/Vs) | | | | | | | | |

TABLE 3

| | | | Comp. |
|---|---|---|---|
| | | Ex. 2 | Ex. 1 |
| Carrier Activation | a | 0.41 | 0.39 |
| Energy | b | 0.46 | 0.38 |
| (eV) | a/b | 0.90 | 1.03 |

TABLE 4

| | | Ex. 2 |
|---|---|---|
| Schottky Barrier | φ_{B30° C.} | 0.46 |
| Height | φ_{B80° C.} | 0.48 |
| (eV) | φ_{B80° C.}/φ_{B30° C.} | 1.04 |

The examples and the comparative example were produced in the following manner. First, a quartz glass ampule was evacuated while being heated, and raw materials were then formulated to have the composition shown in Table 1 and put into the quartz glass ampule. Next, the quartz glass ampule was sealed with an oxygen burner. Next, the sealed quartz glass ampule was placed into a melting furnace and the temperature of the melting furnace was raised to 650° C. to 1000° C. at a rate of 10° C./h to 40° C./h and then held for 6 hours to 12 hours. During the holding time, the quartz glass ampule was turned upside down to stir the melt. Finally, the quartz glass ampule was taken out of the melting furnace and rapidly cooled to room temperature, thus obtaining a variable-resistance material.

The obtained variable-resistance material was measured in terms of oxygen content by the inert gas fusion-infrared absorption method. The results are shown in Table 1.

Next, a switch element was produced using the variable-resistance material as a target. First, a 50 nm thick W electrode was deposited on a Si/SiO₂ substrate. Next, a 100 nm thick SiO₂ insulating layer was deposited on the W electrode. Thereafter, using a focused ion beam system (JIB-4600F, JEOL), a 500 nm diameter hole was formed in the SiO₂ insulating layer and the W electrode. Next, a 150 nm thick variable-resistance material was deposited into the formed hole, thus forming a switch layer. Finally, a 150 nm thick W electrode was further deposited on the switch layer, thus producing a switch element. The deposition was conducted by Ar sputtering under a reduced-pressure atmosphere.

Using the obtained switch element, the OFF current density, the ON current density, the ON/OFF current ratio, and the threshold voltage were determined. The results are shown in Table 2.

The OFF current density, the ON current density, the ON/OFF current ratio, and the threshold voltage were determined in the following manners. First, a 0 V to 10 V voltage was applied to the switch element to measure the values of current that flowed through the switch element and the threshold voltage. The type of voltage to be applied in this case was, for example, a DC voltage, an AC voltage or a pulsed voltage, and was not limited, but, actually, the measurement was conducted using a pulsed voltage from the viewpoint of preventing heat storage of the switch element. The threshold voltage was measured as a voltage value at the time the electrical resistance value of the switch element rapidly changed from a high-resistance state to a low-resistance state. The OFF current density was measured as a value obtained by dividing a value (OFF current value) of a current that flowed through the switch element upon application of one-half the threshold voltage thereto by the contact area of the switch element with an electrode. The ON current density was measured as a value obtained by dividing a value (ON current value) of a current that flowed through the switch element upon application of a voltage not less than the threshold voltage thereto by the contact area of the switch element with the electrode. The ON/OFF current ratio was determined by dividing the ON current value by the OFF current value.

A thin film sample for measuring the carrier mobility was produced by depositing a 150 nm thick variable-resistance material on a Si/SiO₂ substrate by Ar sputtering. The obtained thin film sample was measured in terms of carrier mobility at 30° C. using a resistivity/Hall measurement system (ResiTest8308, manufactured by TOYO Corporation). The results are shown in Table 2.

FIG. 8 shows a graph on which, as for switch layers, the ionicity r_{σ}′ and the hybridization r_{π}⁻¹ are plotted. As shown in FIG. 8, the switch layers in the examples satisfied an ionicity r_{σ}′ of not less than 0.05 and a hybridization r_{π}⁻¹ of not more than 2.0.

As shown in Tables 1 and 2, in the variable-resistance materials in Examples 1 to 7 (Ex. 1 to Ex. 7), the carrier mobility was 2.6×10⁻³ cm²/Vs or less and the OFF current density was 2.55×10² A/cm² or less. Furthermore, the logarithm log₁₀x of the ON/OFF current ratio x was 4.3 to 6.6. On the other hand, in Comparative Example 1 (CEx. 1), the carrier mobility was as large as 5.1×10⁻³ cm²/Vs and the OFF current density was as large as 3.57×10² A/cm². Furthermore, the logarithm log₁₀x of the ON/OFF current ratio x was as small as 3.9.

Table 3 shows changes in carrier activation energies of switch elements when different voltages were applied thereto, and Table 4 shows the relationship between the absolute temperature and the Schottky barrier height in a switch element. As shown in Table 3, in Example 2 (Ex. 2), where a (eV) represents the carrier activation energy of the switch element upon application of an applied voltage of 0.15 V to the switch layer and b (eV) represents the carrier activation energy of the switch element upon application of an applied voltage of 0.30 V to the switch layer, the switch element satisfied a/b<1. As show in Table 4, in Ex. 2, the Schottky barrier height φ_{B80° C.} of the switch element at 80° C. was 1.04 times the Schottky barrier height φ_{B30° C.} thereof at 30° C.

### INDUSTRIAL APPLICABILITY

The variable-resistance material according to the present invention can be suitably used for a switch element that can be used in a resistance-variable memory device, a magnetoresistive memory device, a phase-change memory device, a ferroelectric memory device or other types of memory devices.

### REFERENCE SIGNS LIST

1, 11 first electrode
2, 12 second electrode
3 switch layer
4 switch memory layer
10 switch element
20, 21 memory element
30 word line
40 bit line
100, 101, 200, 201 memory device

1: A variable-resistance material containing Te, wherein when a current density of the variable-resistance material upon application of one-half a threshold voltage thereto is defined as an OFF current density, the OFF current density is not more than 3.1×10² A/cm².

2: The variable-resistance material according to claim 1, wherein, additionally, when a current density of the variable-resistance material upon application of a voltage not less than the threshold voltage thereto is defined as an ON current density, the ON current density is not less than 1×10⁶ A/cm².

3: The variable-resistance material according to claim 1, having a carrier mobility of not more than 5×10⁻³ cm²/Vs.

4: The variable-resistance material according to claim 1, wherein when a current density of the variable-resistance material upon application of a voltage not less than the threshold voltage thereto is defined as an ON current density, an ON/OFF current ratio obtained by dividing the ON current density by the OFF current density is not less than 1×10⁴.

5: The variable-resistance material according to claim 1, wherein the threshold voltage is within a range of 0.5 V to 10 V.

6: The variable-resistance material according to claim 1, containing, in terms of atomic %, 0.1% to 50% Ge and 40% to 90% Te.

7: The variable-resistance material according to claim 1, containing, in terms of atomic %, 1% to 59% Si+Al+Ga+Sn+Bi+Cu+Ag+Zn+Y+In+Ca+Mg.

8: The variable-resistance material according to claim 1, containing, in terms of atomic %, 0% to less than 5% Sb.

9: The variable-resistance material according to claim 1, being substantially free of Sb, Se, and As.

10: The variable-resistance material according to claim 1, having an oxygen content of less than 1 atomic %.

11: The variable-resistance material according to claim 1, being a thin film.

12: A material for a switch element, the material being made of the variable-resistance material according to claim 1.

13: A switch layer made of the variable-resistance material according to claim 1.

14: A switch element comprising:
the switch layer according to claim 13; and
a first electrode disposed on the switch layer.

15: A switch element comprising:
a switch layer;
a first electrode disposed on the switch layer; and
a second electrode opposed to the first electrode with the switch layer in between,
wherein the switch layer is made of a variable-resistance material which contains Te and in which when a current density of the variable-resistance material upon application of one-half a threshold voltage thereto is defined as an OFF current density, the OFF current density is not more than 3.1×10² A/cm².

16: The switch element according to claim 15, wherein
the first electrode is disposed on an outer periphery of the switch layer, and
the second electrode is disposed on an inner periphery of the switch layer.

17: The switch element according to claim 15, wherein the first electrode and the second electrode are at least one selected from among tungsten, titanium, copper, platinum, tungsten nitride, and titanium nitride.

18: The switch element according to claim 15, wherein an ionicity r_{σ}′ and a hybridization r_{π}⁻¹ of the switch layer satisfy the respective following values:
r_{σ}′≥0.05
r_{π}⁻¹≤2.0

19: The switch element according to claim 15, wherein where a represents a carrier activation energy of the switch element upon application of an applied voltage of 0.15 V to the switch layer and b represents a carrier activation energy of the switch element upon application of an applied voltage of 0.30 V to the switch layer, the switch element satisfies a/b<1.

20: A memory device comprising the switch element according to claim 15.

21: A memory device comprising:
the switch element according to claim 15; and
a memory element.

22: A memory device comprising a laminate in which a switch element and a memory element are layered, wherein
the switch element comprises a switch layer and a first electrode disposed on the switch layer,
the switch layer is made of a variable-resistance material in which when a current density of the variable-resistance material upon application of one-half a threshold voltage thereto is defined as an OFF current density, the OFF current density is not more than 3.1×10² A/cm², and
the memory element is made of at least one of a variable-resistance memory element, a magnetoresistive memory element, a phase-change memory element, and a ferroelectric memory element.
